(19) United States
(12) Patent Application Publication
(10) Pub. No.: US 2025/0385094 A1
(43) Pub. Date: Dec. 18, 2025

(54) DOPED SILICON CARBIDE SUBSTRATE AND METHOD OF MANUFACTURING SAME

(71) Applicant: GlobalWafers Co., Ltd., Hsinchu (TW)

(72) Inventors: Wei Fan Tsai, Hsinchu (TW); Chih Shan Tan, Hsinchu (TW); Ching-Shan Lin, Hsinchu (TW)

(73) Assignee: GlobalWafers Co., Ltd., Hsinchu (TW)

(21) Appl. No.: 19/181,323

(22) Filed: Apr. 16, 2025

(30) Foreign Application Priority Data
Jun. 12, 2024 (TW) 113121600

(51) Int. Cl. H01L 21/04; C01B 32/956; C30B 29/36; H10D 62/832

(52) U.S. Cl. CPC H01L 21/046; C01B 32/956; C30B 29/36; H10D 62/8325; C01P 2002/52; C01P 2002/77; C01P 2006/40

(57) ABSTRACT

A method for manufacturing a semiconductor substrate includes steps as follows. An n-type 4H silicon carbide standard model is established. A semi-insulating 4H silicon carbide standard model is established. A simulation software is used to introduce a doping element into at least one of the n-type 4H silicon carbide standard model and the semi-insulating 4H silicon carbide standard model to calculate a simulated resistivity of a 4H silicon carbide doped with the doping element. The doping element is used to dope a silicon carbide substrate to obtain a doped silicon carbide substrate.

### CROSS-REFERENCE TO RELATED APPLICATION

This application claims the priority benefit of Taiwan application serial no. 113121600, filed on Jun. 12, 2024. The entirety of the above-mentioned patent application is hereby incorporated by reference herein and made a part of this specification.

### BACKGROUND

### Technical Field

The disclosure relates to a semiconductor substrate and a method for manufacturing the same.

### Related Art

Silicon carbide wafers have characteristics such as high power, high voltage resistance, and high temperature resistance. These characteristics have attracted attention and emphasis from the industry, making it a strategic industry with enormous growth potential. Generally, silicon carbide wafers may be classified according to the resistivity thereof into low resistivity n-type silicon carbide (also known as conductive type silicon carbide) and high resistivity semi-insulating silicon carbide (Semi-insulating Silicon Carbide, SI-SiC). Different types of silicon carbide have different applications. For example, low resistivity n-type silicon carbide is commonly used in the electric vehicle field, while high resistivity semi-insulating silicon carbide is commonly used in the communication field.

Generally, silicon carbide is doped to fabricate n-type silicon carbide or semi-insulating silicon carbide. However, in order to find suitable doping elements, a significant amount of time and money has to be spent to fabricate and test silicon carbide doped with various different doping elements to confirm whether the silicon carbide doped with different types of doping elements meets the requirements.

### SUMMARY

The disclosure provides a semiconductor substrate and a method for manufacturing the same. In some embodiments of the disclosure, before fabricating a doped silicon carbide substrate, a simulation method is first used to calculate a simulated resistivity to ensure that the silicon carbide substrate doped with the selected doping element can meet the requirements. Since the simulation software is used to calculate the resistivity of the doped silicon carbide substrate to be manufactured, the operation can save the money and time costs required to find suitable doping elements.

At least one embodiment of the disclosure provides a method for manufacturing a semiconductor substrate, which includes steps as follows. A simulation software is used to add a first dopant in a 4H silicon carbide supercell to obtain an n-type 4H silicon carbide supercell. The simulation software is used to add a second dopant in another 4H silicon carbide supercell to obtain a semi-insulating 4H silicon carbide supercell. The simulation software is used to perform free energy structure optimization simulation of the n-type 4H silicon carbide supercell to establish an n-type 4H silicon carbide standard model. The simulation software is used to perform free energy structure optimization simulation of the semi-insulating 4H silicon carbide supercell to establish a semi-insulating 4H silicon carbide standard model. The simulation software is used to introduce a doping element into at least one of the n-type 4H silicon carbide standard model and the semi-insulating 4H silicon carbide standard model to calculate a simulated resistivity of 4H silicon carbide doped with the doping element. The doping element is used to dope a silicon carbide substrate to obtain a doped silicon carbide substrate.

At least one embodiment of the disclosure provides a semiconductor substrate, which includes a silicon carbide substrate, in which the silicon carbide substrate is doped with at least one of Ta, P, As, Sb, Bi, F, Cl, I, At, B, Al, Ga, In, and Tl.

### BRIEF DESCRIPTION OF THE DRAWINGS

FIG. 1 is a schematic diagram of a 4H silicon carbide unit cell according to an embodiment of the disclosure.

FIG. 2 is a flowchart of a method for manufacturing a semiconductor substrate

according to an embodiment of the disclosure.

FIG. 3A is a schematic diagram of a crystal structure corresponding to an n-type 4H silicon carbide standard crystal model according to an embodiment of the disclosure.

FIG. 3B is a schematic diagram of a crystal structure corresponding to a semi-insulating 4H silicon carbide standard model according to an embodiment of the disclosure.

FIG. 4A is a flowchart of establishing an n-type 4H silicon carbide standard model according to an embodiment of the disclosure.

FIG. 4B is a flowchart of establishing a semi-insulating 4H silicon carbide standard model according to an embodiment of the disclosure.

FIG. 5A, 5B, 5C, 5D, and 5E are respectively an energy band diagram of Ta-doped 4H silicon carbide, an energy band diagram of Cl-doped 4H silicon carbide, an energy band diagram of I-doped 4H silicon carbide, an energy band diagram of At-doped 4H silicon carbide, and an energy band diagram of F-doped 4H silicon carbide according to an embodiment of the disclosure.

FIG. 6A, 6B, 6C, 6D, and 6E are respectively crystal structures of doped 4H silicon carbide corresponding to FIG. 5A, 5B, 5C, 5D, and 5E.

### DESCRIPTION OF THE EMBODIMENTS

In some embodiments, the simulation software used in this disclosure includes Vienna Ab initio Simulation Package (VASP). In some embodiments, all simulations involving first principle calculations are performed using VASP simulation software.

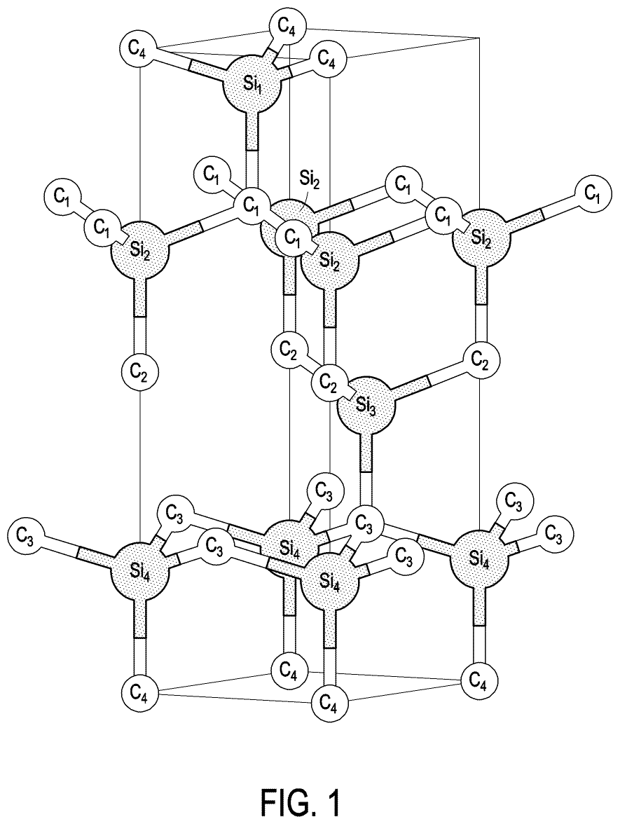

Referring to FIG. 1, a 4H silicon carbide unit cell of 1×1×1 is established in the VASP simulation software. In the 4H silicon carbide unit cell, according to different positions, silicon atoms may be divided into silicon atom Si₁, silicon atom Si₂, silicon atom Si₃, and silicon atom Si₄, while carbon atoms may be divided into carbon atom C₁, carbon atom C₂, carbon atom C₃, and carbon atom C₄. In some embodiments, implanting doping elements into the 4H silicon carbide unit cell may change the Gibbs free energy of the structure. Table 1 shows the simulation results of changes in Gibbs free energy caused by substituting silicon atoms or carbon atoms in the 4H silicon carbide unit cell with nitrogen atoms (N). Table 2 shows the simulation results of changes in Gibbs free energy caused by substituting silicon atoms or carbon atoms in the 4H silicon carbide unit cell with vanadium atoms (V).

TABLE 1

| Atomic position | |
|---|---|
| of nitrogen | Gibbs free |
| atom substitution | energy (eV) |
| pure 4H silicon | −60.18 |
| carbide unit cell | |
| carbon atom C₁ | −58.98 |
| carbon atom C₂ | −59.00 |
| carbon atom C₃ | −58.98 |
| carbon atom C₄ | −59.00 |
| silicon atom Si₁ | −57.84 |
| silicon atom Si₂ | −57.83 |
| silicon atom Si₃ | −57.84 |
| silicon atom Si₄ | −57.83 |

TABLE 2

| Atomic position | |
|---|---|
| of vanadium | Gibbs free |
| atom substitution | energy (eV) |
| pure 4H silicon | −60.18 |
| carbide unit cell | |
| carbon atom C₁ | −57.65 |
| carbon atom C₂ | −57.66 |
| carbon atom C₃ | −57.65 |
| carbon atom C₄ | −57.66 |
| silicon atom Si₁ | −62.36 |
| silicon atom Si₂ | −62.20 |
| silicon atom Si₃ | −62.36 |
| silicon atom Si₄ | −62.20 |

From FIG. 1 and Table 1. it may be understood that substituting carbon atoms in the 4H silicon carbide unit cell with nitrogen atoms may lower the free energy of the structure and make the structure more stable. On the other hand, from FIG. 1 and Table 2, it may be understood that substituting silicon atoms in the 4H silicon carbide unit cell with vanadium atoms may lower the free energy of the structure and make the structure more stable. In the simulation process, atoms may move slightly in 3-dimensional space and move to the most suitable position, thereby obtaining a more stable structure.

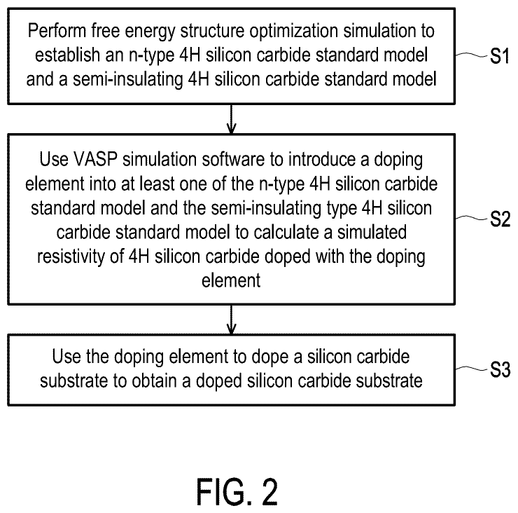

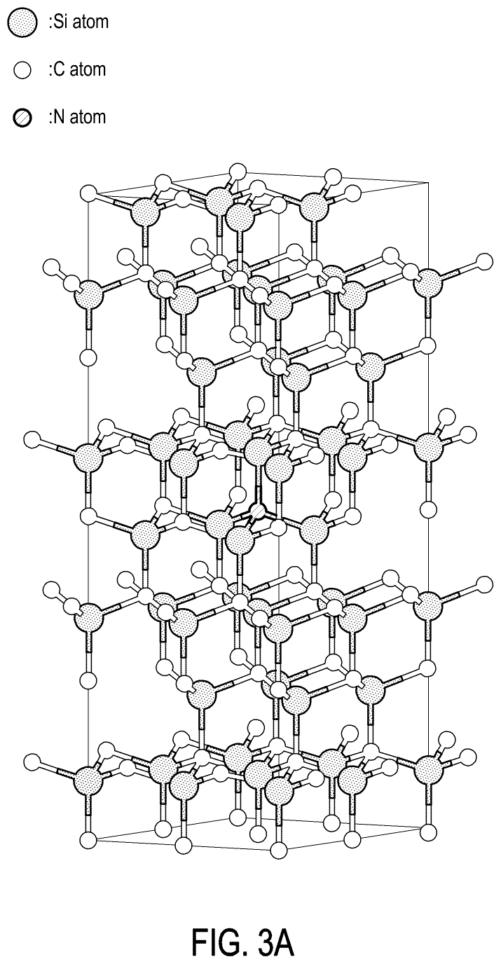

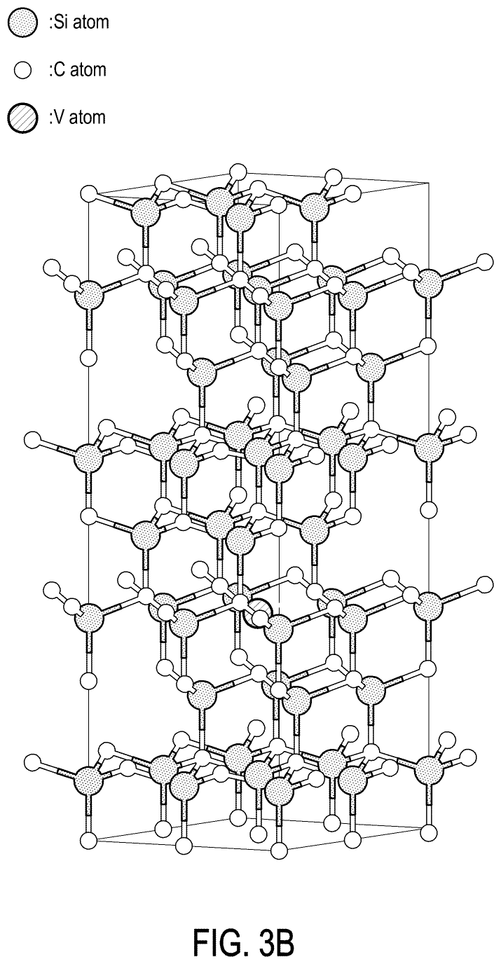

FIG. 2 is a flowchart of a method for manufacturing a semiconductor substrate according to an embodiment of the disclosure. In Step S1, the VASP simulation software is used to perform free energy structure optimization simulation to establish an n-type 4H silicon carbide standard model and a semi-insulating 4H silicon carbide standard model. The crystal structure corresponding to the n-type 4H silicon carbide standard model is shown in FIG. 3A, and the crystal structure corresponding to the semi-insulating 4H silicon carbide standard model is shown in FIG. 3B.

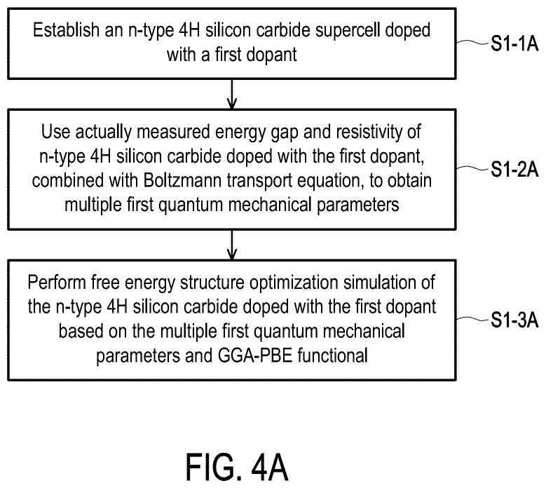

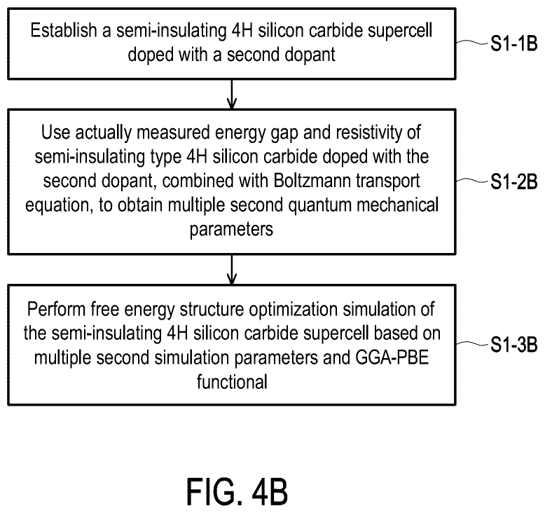

FIG. 4A is a flowchart of establishing an n-type 4H silicon carbide standard model. First, in Step S1-1A, the VASP simulation software is used to establish an n-type 4H silicon carbide supercell. Specifically, 4H silicon carbide unit cells (as shown in FIG. 1) are repeatedly arranged to obtain a 4H silicon carbide supercell of 2×2×2, and a first dopant (for example, nitrogen) is added to the 4H silicon carbide supercell to obtain the n-type 4H silicon carbide supercell, in which the first dopant substitutes one of carbon elements or silicon elements in the 4H silicon carbide supercell. For example, based on the results in Table 1, a nitrogen atom is added to the 4H silicon carbide supercell of 2×2×2, in which the nitrogen atom substitutes the position of a carbon atom.

Similarly, in Step S1-1B in FIG. 4B, the VASP simulation software is used to establish a semi-insulating 4H silicon carbide supercell. Specifically, 4H silicon carbide unit cells (as shown in FIG. 1) are repeatedly arranged to obtain another 4H silicon carbide supercell of 2×2×2, and a second dopant (for example, vanadium) is added to the other 4H silicon carbide supercell to obtain the semi-insulating 4H silicon carbide supercell, in which the second dopant substitutes one of carbon elements or silicon elements in the 4H silicon carbide supercell. For example, based on the results in Table 2, a vanadium atom is doped into the 4H silicon carbide supercell of 2×2×2, in which the vanadium atom substitutes the position of a silicon atom.

In some embodiments, in addition to establishing the n-type 4H silicon carbide supercell and the semi-insulating 4H silicon carbide supercell, a pure 4H silicon carbide supercell (that is, a 4H silicon carbide supercell without doping elements) of 2×2×2 may also be established.

In some embodiments, during the process of establishing the n-type 4H silicon carbide supercell, the semi-insulating 4H silicon carbide supercell, and the pure 4H silicon carbide supercell, the functional used for calculating the exchange correlation energy is the generalized gradient approximation (GGA) modified with Perdew-Burke-Ernzerhof (PBE) correction, namely the GGA-PBE functional. The GGA-PBE functional may be represented by Mathematical Equation 1.

$${E}_{xc}^{( GAA )} [ n ] = \int {ε}_{xc} ( n ( r ) , ∇ n ( r ) ) dr = \int {ε}_{xc}^{( LDA )} ( n ( r ) ) {F}_{xc} ( {r}_{s} ( r ) , s ( r ) ) dr \qquad Mathematical Equation 1$$

In the GGA-PBE functional, ε_{xc} is used to represent the exchange correlation energy density; n(r) is used to represent the electron density of the system; ∇n(r) is used to represent the electron density gradient of the system; ε_{xc}^{(LDA)} is the exchange correlation energy density of the local density approximation (LDA), which differs from ε_{xc} in that ε_{xc}^{(LDA)} is a functional that only relates to n(r), while ε_{xc}, in addition to being related to n(r), is also related to the derivatives (the derivatives may be first-order or higher-order derivatives) of n(r) in different directions in space. In other words, if non-uniform electron density is considered, then the electron density at various positions in the system have differences, and these differences may be described using the concept of gradient, so ε_{xc}, in addition to being related to electron density, also includes concepts related to the electron density gradient.

Fxc is the enhancement factor, in which Fxc=Fx(s)+Fc(rs,s), Fx is the exchange term, and Fc is the correlation term. rs is the Wigner-Seitz radius, and s is the reduced density gradient. Fx is a functional of s, and Fc is a functional of both rₛ and s, while both rₛ and s are functionals of n(r), where

$${r}_{s} = {[ \frac{3}{4 π n ( r )} ]}^{\frac{1}{3}} , s = \frac{Vn ( r ) \cdot Vn ( r )}{n ( r )} .$$

The GGA-PBE functional is the most widely applied functional in GGA functionals. Whether the system is finite or infinite, the GGA-PBE functional may obtain accurate simulation results. In addition, good predictions may be obtained through GGA-PBE for solid materials with 3d orbitals of transition metals.

In some embodiments, the plane wave cutoff energy used in the GGA-PBE functional

involved in establishing the n-type 4H silicon carbide supercell, the semi-insulating 4H silicon carbide supercell, and the pure 4H silicon carbide supercell is of 200 eV to 550 eV, the spacing of k points is of 0.1/Ang to 0.5/Ang, and the self-consistent field energy convergence (SCF convergence) is of 10⁻⁵ to 10⁻⁷ eV. In some embodiments, the higher the plane wave cutoff energy value, the longer the time required for simulation calculation; the smaller the spacing of k points and self-consistent field energy convergence, the longer the time required for simulation calculation. Therefore, when starting the simulation, parameters requiring shorter simulation calculation time are selected first. Afterward, the simulation parameters are adjusted to gradually increase the complexity of the simulation calculation, so that the results of the simulation calculation match the expected results.

Next, returning to FIG. 4A, in Step S1-2A, the actually measured energy gap and resistivity of the n-type 4H silicon carbide doped with the first dopant are used, combined with the Boltzmann transport equation, to obtain multiple first quantum mechanical parameters (including the plane wave cutoff energy, the spacing of k points, and the self-consistent field energy convergence). Specifically, the Boltzmann transport equation may be represented by

Mathematical Equation 2.

$$\frac{\partial f}{\partial t} + \vec{ν} \cdot ∇ f + \frac{e \vec{E}}{ℏ} \cdot {∇}_{k} f = {( \frac{\partial f}{\partial t} )}_{coll} \qquad Mathematical Equation 2$$

For the Boltzmann transport equation, ∇f is the partial derivative of the electron distribution function f with respect to a position r, and ∇ₖf is the partial derivative of the electron distribution function f with respect to a wave vector k. e represents the charge, and ℏ represents the Planck constant. Since the electron distribution function f itself is a function of both the position r and the wave vector k, the Fermi level is adjusted to modify r, thereby adjusting the electron distribution function f, and then the adjusted electron distribution function f is used in the Boltzmann transport equation to solve for the electron velocity \vec{v}, the electric field intensity \vec{E}, and the scattering term

$${( \frac{\partial f}{\partial t} )}_{coll} .$$

In the VASP simulation software, by inputting the energy gap of the material and quantum mechanical parameters (including the plane wave cutoff energy, the spacing of k points, and the self-consistent field energy convergence), the resistivity of the material may be calculated based on the Boltzmann transport equation. For example, the electron velocity may be solved through the Boltzmann transport equation, and the electron current density may be derived from the integral of electron charge, electron velocity, and electron momentum distribution function. Ohm's law may derive the conductivity of the material from the electron current density, and the obtained conductivity is the reciprocal of resistivity. Based on above, with the energy gap and resistivity of the material, combined with the Boltzmann transport equation, the corresponding quantum mechanical parameters may be obtained.

Similarly, in Step S1-2B in FIG. 4B, the actually measured energy gap and resistivity of the semi-insulating type 4H silicon carbide doped with the second dopant are used, combined with the Boltzmann transport equation, to obtain multiple second quantum mechanical parameters (including the plane wave cutoff energy, the spacing of k points, and the self-consistent field energy convergence).

In some embodiments, multiple third quantum mechanical parameters (including the plane wave cutoff energy, the spacing of k points, and the self-consistent field energy convergence) are additionally obtained by using the energy gap and resistivity of the pure 4H silicon carbide, combined with the Boltzmann transport equation.

In some embodiments, the resistivity of the pure 4H silicon carbide is of 1 ohm-cm to 10 ohm-cm, the resistivity of the nitrogen-doped 4H silicon carbide is of 1.5×10⁻² ohm-cm to 2.5×10⁻² ohm-cm, and the resistivity of the vanadium-doped 4H silicon carbide is of 10¹⁰ ohm-cm to 10¹² ohm-cm.

In some embodiments, the energy gap of the pure 4H silicon carbide, the energy gap of the nitrogen-doped 4H silicon carbide, and the energy gap of the vanadium-doped 4H silicon carbide are measured using Ultraviolet-visible spectroscopy (UV-Vis). In some embodiments, the energy gap of the pure 4H silicon carbide is of 3.2 eV to 3.3 eV, and the nitrogen-doped 4H silicon carbide and the vanadium-doped 4H silicon carbide may have an additional energy level due to doping.

In Step S1-3A in FIG. 4A, the VASP simulation software is used to perform free energy structure optimization simulation of the n-type 4H silicon carbide doped with the first dopant (that is, the n-type 4H silicon carbide supercell) based on the multiple first quantum mechanical parameters obtained in Step S1-2A and the GGA-PBE functional to establish an n-type 4H silicon carbide standard model. In some embodiments, the n-type 4H silicon carbide standard model is nitrogen-doped silicon carbide, and through the VASP simulation software, the Fermi level (that is, a first Fermi level) of the n-type 4H silicon carbide standard model may be simulated and calculated, for example, at a position 2.56 eV above the valence band.

Similarly, in Step S1-3B in FIG. 4B, the VASP simulation software is used to perform free energy structure optimization simulation of the semi-insulating type 4H silicon carbide doped with the second dopant based on the multiple second quantum mechanical parameters obtained in Step S1-2B and the GGA-PBE functional to establish a semi-insulating type 4H silicon carbide standard model. In some embodiments, the semi-insulating type 4H silicon carbide standard model is vanadium-doped silicon carbide, and through the VASP simulation software, the Fermi level (that is, a second Fermi level) of the semi-insulating type 4H silicon carbide standard model may be simulated and calculated, for example, at a position 0.99 eV above the valence band.

In some embodiments, the VASP simulation software and multiple third quantum mechanical parameters corresponding to the pure 4H silicon carbide and the GGA-PBE functional are used to perform free energy structure optimization simulation of the pure 4H silicon carbide to establish a pure 4H silicon carbide standard model.

In the embodiments of the disclosure, by correcting the results obtained from the free energy structure optimization simulation through the Boltzmann transport equation, the energy gap underestimation problem caused by the first principle may be improved. Compared with the n-type 4H silicon carbide model and the semi-insulating type 4H silicon carbide model obtained without correcting the energy gap underestimation problem, the n-type 4H silicon carbide standard model and the semi-insulating type 4H silicon carbide standard model obtained in this embodiment better match the actually fabricated n-type 4H silicon carbide and semi-insulating type 4H silicon carbide. Therefore, using the n-type 4H silicon carbide standard model and the semi-insulating type 4H silicon carbide standard model for subsequent simulation can obtain more accurate simulation results.

Next, returning to FIG. 2, in Step S2, the VASP simulation software is used to introduce a doping element into at least one of the n-type 4H silicon carbide standard model and the semi-insulating type 4H silicon carbide standard model to calculate a simulated resistivity of 4H silicon carbide doped with the doping element. In some embodiments, the doping element includes one of Ta, P, As, Sb, Bi, F, Cl, I, At, B, Al, Ga, In, and Tl.

Specifically, the VASP simulation software contains models of different elements, and models of these element are established based on characteristics such as the electronic structure, and the atomic radius of the elements. In the VASP simulation software, the n-type 4H silicon carbide standard model is used to simulate and calculate a first simulated resistivity of the 4H silicon carbide doped with the selected element, with results shown in Table 3. Additionally, in the VASP simulation software, the semi-insulating type 4H silicon carbide standard model is used to simulate and calculate a second simulated resistivity of 4H silicon carbide doped with the selected element, with results shown in Table 4.

TABLE 3

| | First | Whether suitable |
|---|---|---|
| | simulated | for n-type 4H |
| Doping | resistivity | silicon carbide |
| element | (ohm cm) | standard model |
| pure 4H | 5.39 | Yes |
| silicon | | |
| carbide | | |
| N | 1.14 × 10⁻² | Yes |
| Ta | 1.62 × 10⁻² | Yes |
| P | 1.3 × 10⁻² | Yes |
| As | 1.4 × 10⁻² | Yes |
| Sb | 5.07 × 10⁻³ | Yes |
| Bi | 2.06 × 10⁻² | Yes |
| F | 2.28 × 10⁻² | No |
| Cl | ∞ (conductivity | No |
| | approaching 0) | |
| I | ∞ (conductivity | No |
| | approaching 0) | |
| At | ∞ (conductivity | No |
| | approaching 0) | |

TABLE 4

| | Second | Whether suitable |
|---|---|---|
| | simulated | for semi-insulating |
| Doping | resistivity | 4H silicon carbide |
| element | (ohm cm) | standard model |
| pure 4H | 1.89 | Yes |
| silicon | | |
| carbide | | |
| V | 3.47 × 10¹¹ | Yes |
| F | ∞ (conductivity | Yes |
| | approaching 0) | |
| Cl | 3.84 × 10⁻³ | Yes |
| I | 6.19 × 10⁻³ | Yes |
| At | 5.08 × 10⁻³ | Yes |
| B | 8.46 × 10⁻⁴ | Yes |
| Al | 8.19 × 10⁻⁴ | Yes |
| Ga | 8.22 × 10⁻⁴ | Yes |
| In | 8.8 × 10⁻⁴ | Yes |
| Tl | 1.13 × 10⁻³ | Yes |

The resistivity of pure 4H silicon carbide without doping at 300K, simulated from the n-type 4H silicon carbide standard model and the semi-insulating type 4H silicon carbide standard model, is of 1 ohm-cm to 10 ohm-cm, which is close to the actually measured resistivity of pure 4H silicon carbide. Additionally, the resistivity of nitrogen-doped 4H silicon carbide at 300K, simulated from the n-type 4H silicon carbide standard model, is 1.14×10⁻² ohm-cm, which is close to the resistivity of actual nitrogen-doped 4H silicon carbide (approximately 10⁻² ohm-cm). The resistivity of vanadium-doped 4H silicon carbide at 300K, simulated from the semi-insulating type 4H silicon carbide standard model, is 3.47×10¹¹ ohm-cm, which is close to the resistivity of actual vanadium-doped 4H silicon carbide (approximately 10¹⁰ to 10¹² ohm-cm).

In some embodiments, the energy band diagram, Deep Level Transient Spectroscopy (DLTS), and/or Hall measurement of 4H silicon carbide doped with the selected doping element are used to confirm whether the selected doping element is suitable for the n-type 4H silicon carbide standard model or the semi-insulating type 4H silicon carbide standard model. Hall measurement is used to determine whether a carrier type of the 4H silicon carbide doped with the doping element is an electrons or a hole. Based on the carrier type, it is determined whether the doping element is suitable for the n-type 4H silicon carbide standard model or the semi-insulating type 4H silicon carbide standard model.

In some embodiments, the energy band diagram of doped 4H silicon carbide is obtained through Hybrid (GGA) functional simulation in the VASP simulation software. The Hybrid (GGA) functional may be expressed by Mathematical Equation 3.

$${E}_{xc}^{( Hybrid )} [ n ] = {aE}_{x}^{exact} + ( 1 - a ) {E}_{x}^{DFT} + {bE}_{c}^{exact} + ( 1 - b ) {E}_{c}^{DFT} \qquad Mathematical Equation 3$$

In Mathematical Equation 3, Eₓ^{exact} is the accurate exchange energy, E_{c}^{exact} is the accurate correlation energy, Eₓ^{DFT} is the approximate exchange energy of Density Functional Theory (DFT), and E_{c}^{DFT} is the approximate correlation energy of DFT. These terms may be individually derived during the derivation process of the first principle mathematical equation. Parameters a and b represent the proportions of different terms, where the parameter a is related to the exchange energy term of the functional, and the parameter b is related to the correlation energy term of the functional. The determination of a and b depends on, for example, the system type, computational cost, exchange terms, and correlation terms. The range of both parameters satisfies [0,1] (that is, all real numbers from 0 to 1). Increasing the values of a and b means increasing the proportion of accurate terms in the mathematical equation. Under the framework of the first principle, it is difficult to describe the complete accurate term using mathematical equations, so the Hartree-Fock equation is used instead. The energy operator of the Hartree-Fock equation is simplified merely through the Born-Oppenheimer approximation and corrects the mathematical description of the wave function, and thus the description of the energy operator is relatively more complete compared to the first principle.

In some embodiments, the plane wave cutoff energy used in the Hybrid-GGA functional is of 200 eV to 550 eV, the spacing of k points is of 0.1/Ang to 0.5/Ang, and the self-consistent field energy convergence (SCF convergence) is of 10⁻⁵ to 10⁻⁷ eV. In some embodiments, the simulation based on the Hybrid-GGA functional is performed using the previously obtained multiple third quantum mechanical parameters corresponding to pure 4H silicon carbide calculated via the Boltzmann transport equation.

After obtaining the energy band diagrams of 4H silicon carbide doped with various doping elements using the Hybrid-GGA functional, the first Fermi level (2.56 eV) and the second Fermi level (0.99 eV) are used to determine whether the standard model suitable for the selected doping element is the n-type 4H silicon carbide standard model or the semi-insulating 4H silicon carbide standard model. When the first simulated resistivity (refer to Table 3) corresponds to the energy band diagram of the 4H silicon carbide doped with the doping element and the first Fermi level, the standard model suitable for the selected doping element is the n-type 4H silicon carbide standard model, and the first simulated resistivity (refer to Table 3) is the simulated resistivity of 4H silicon carbide doped with the doping element. When the second simulated resistivity (refer to Table 4) corresponds to the energy band diagram of 4H silicon carbide doped with the doping element and the second Fermi level, the standard model suitable for the selected doping element is the semi-insulating 4H silicon carbide standard model, and the second simulated resistivity (refer to Table 4) is the simulated resistivity of 4H silicon carbide doped with the doping element. The method for determining the standard model will be illustrated with energy band diagrams in the following examples.

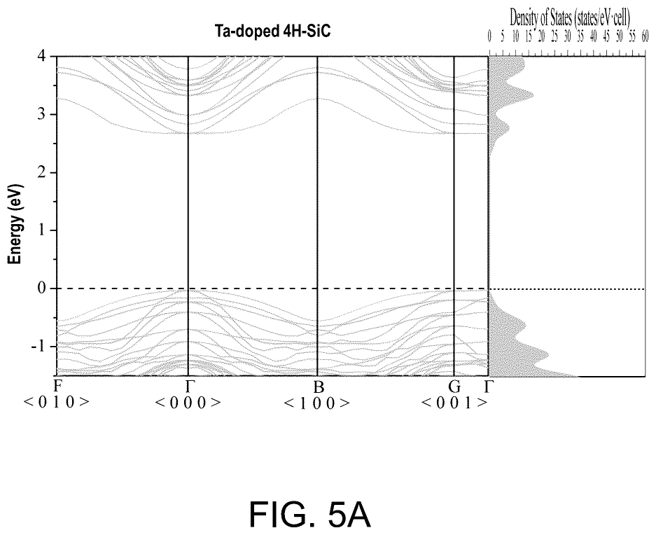

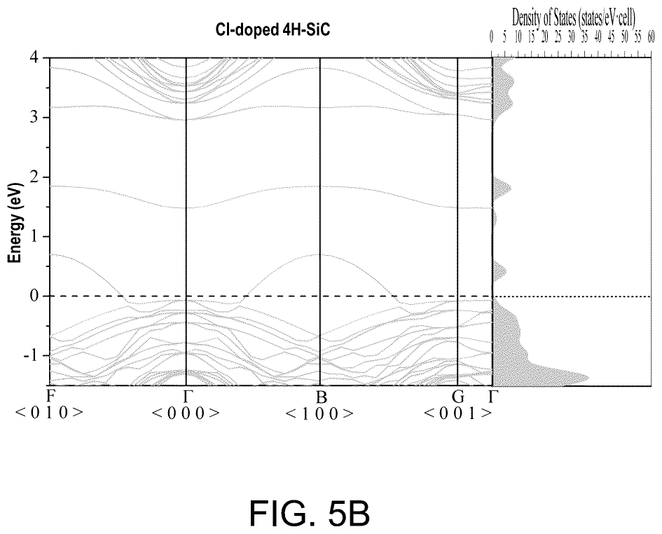

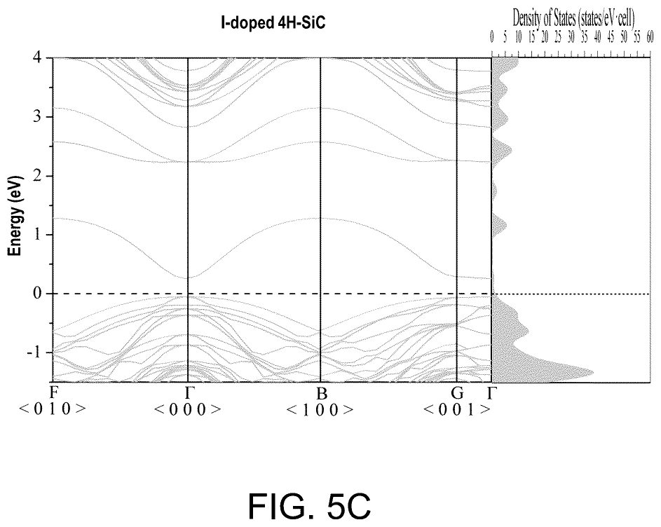

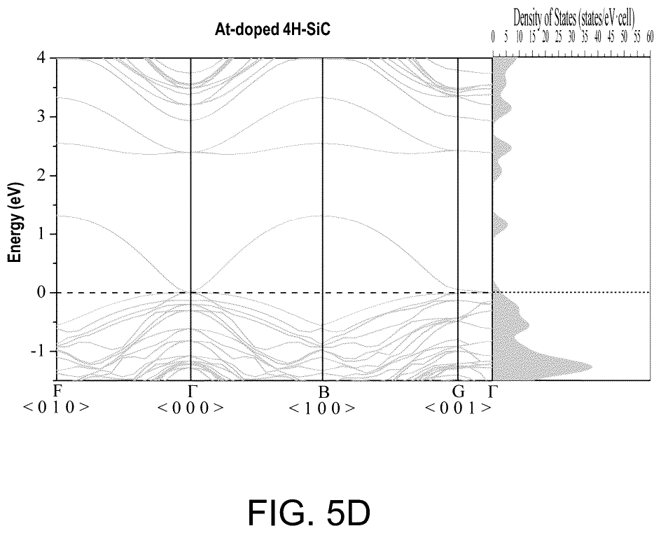

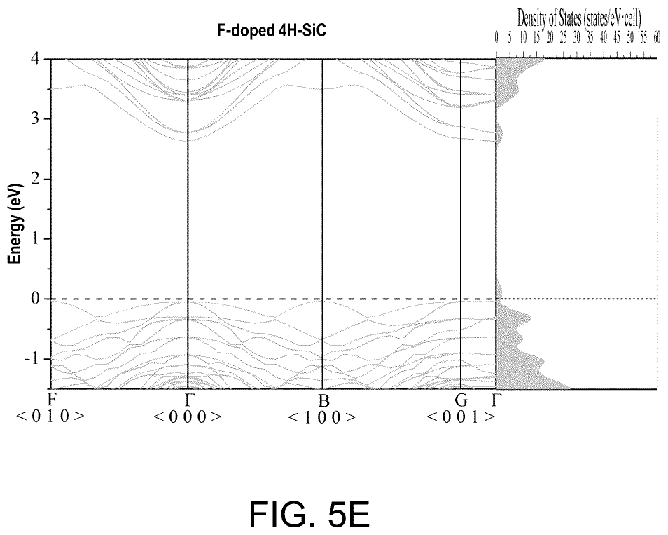

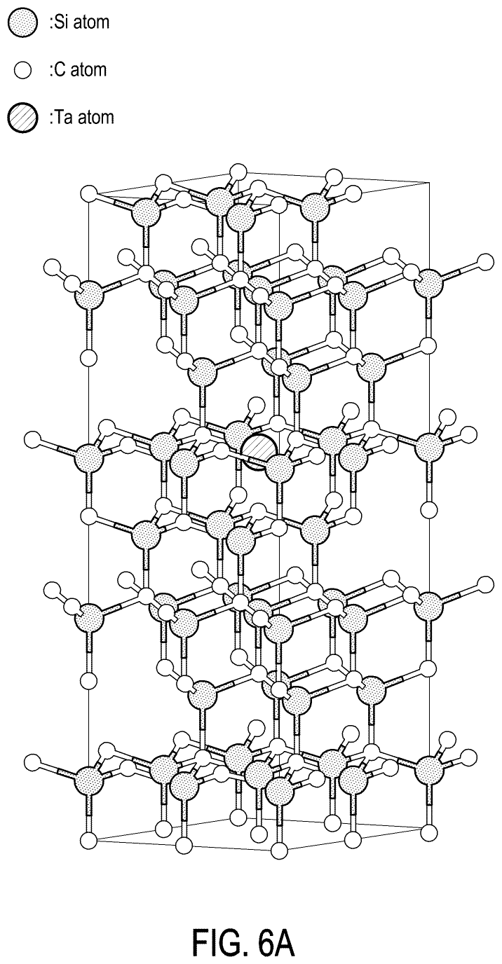

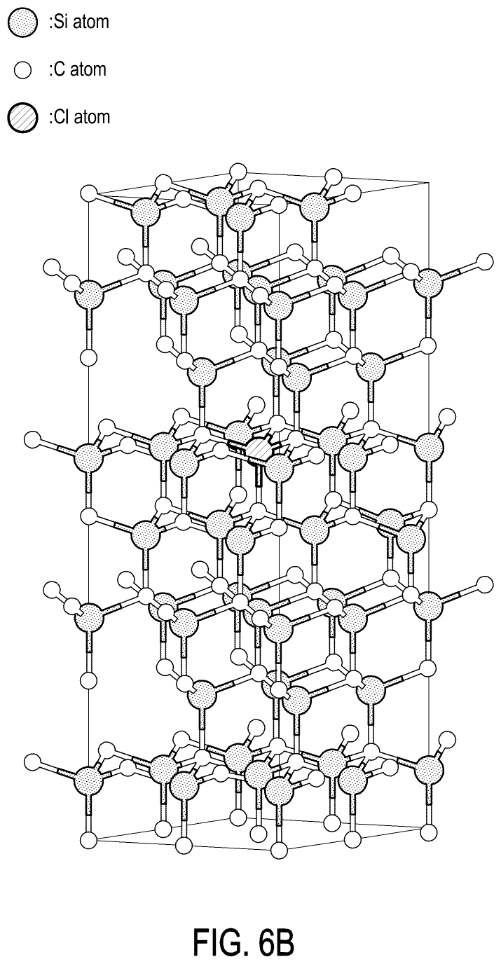

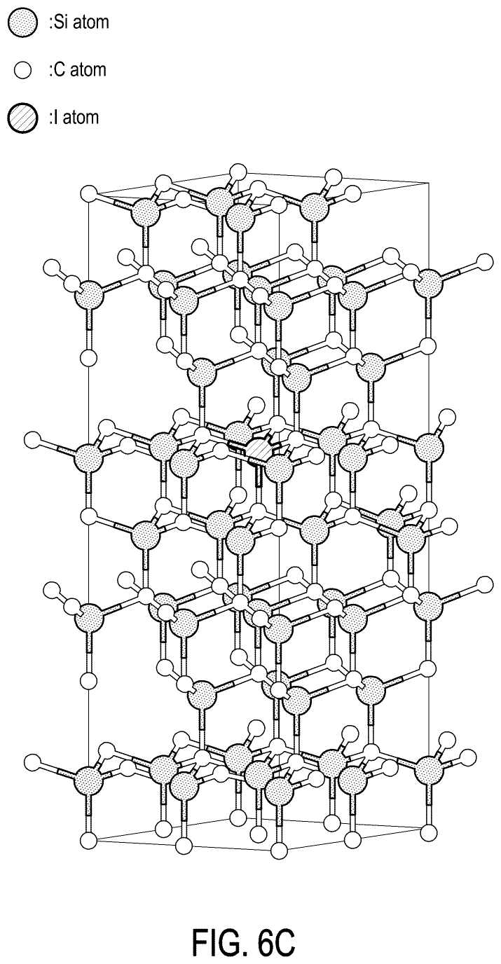

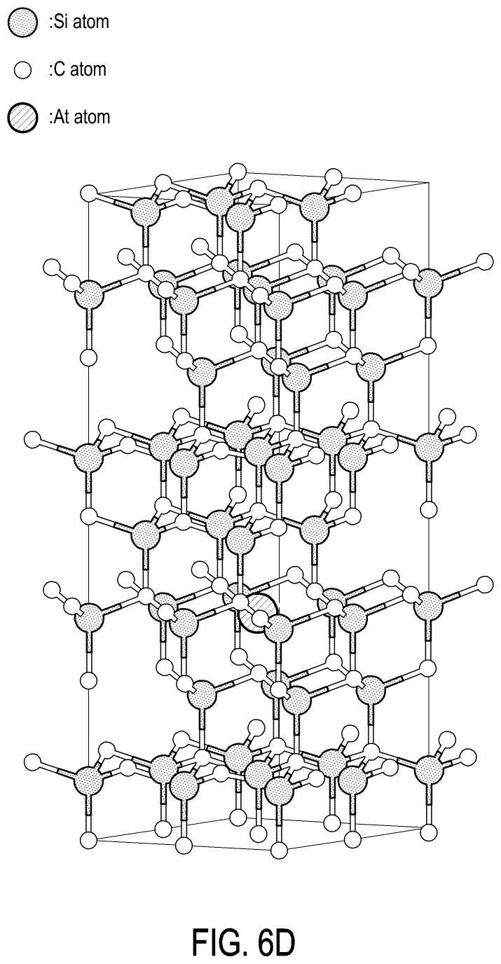

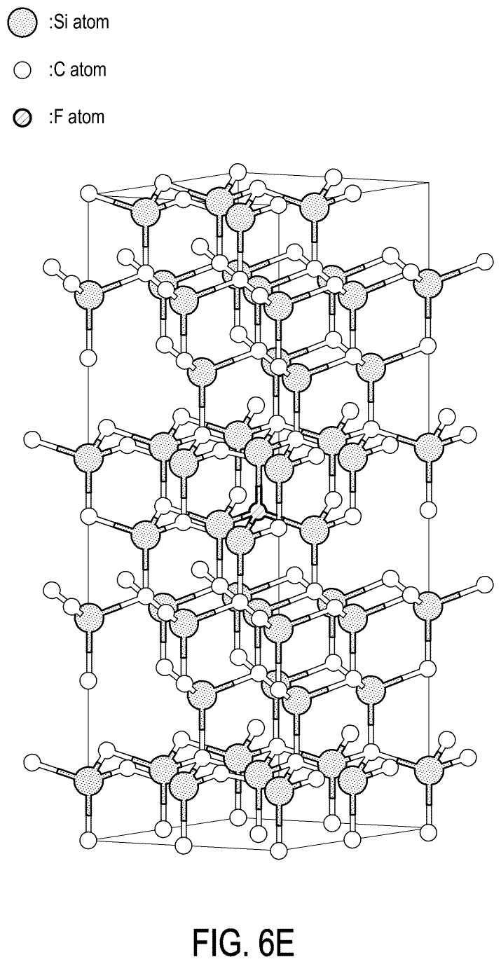

FIG. 5A, 5B, 5C, 5D, and 5E are respectively an energy band diagram of Ta-doped 4H silicon carbide, an energy band diagram of Cl-doped 4H silicon carbide, an energy band diagram of I-doped 4H silicon carbide, an energy band diagram of At-doped 4H silicon carbide, and an energy band diagram of F-doped 4H silicon carbide. FIG. 6A, 6B, 6C, 6D, and 6E are respectively crystal structures of doped 4H silicon carbide corresponding to FIG. 5A, 5B, 5C, 5D, and 5E.

Referring to FIG. 5B and FIG. 6B, after Cl is doped into 4H—SiC, energy levels are generated not only near the valence band and conduction band, but also additional energy levels are generated in the energy gap. Therefore, when E_{F}=0.99+E_{V} eV, holes may occupy B<1 0 0>, and in addition to releasing energy, by changing phonons, may move to the Γ point, resulting in low resistivity. When E_{F}=2.56+E_{V} eV, Cl is doped into 4H—SiC, additional energy levels are near the middle of the energy gap for electrons to occupy and transition, so the resistivity should be lower than undoped 4H—SiC. However, the calculated resistivity result is o (refer to Table 3), which conflicts with the density of states and energy band results, and indicates that the resistivity value of Cl-doped 4H—SiC is not suitable for the standard model with E_{F}=2.56+E_{V} eV (that is, not suitable for the n-type 4H silicon carbide standard model). Using the semi-insulating 4H silicon carbide standard model for simulation calculations of Cl-doped 4H—SiC may obtain more accurate results.

Referring to FIG. 5C, FIG. 6C, 5D and 6D, the density of states and energy band diagrams of I-doped 4H—SiC and At-doped 4H—SiC are very similar. Compared with undoped 4H—SiC, the energy band diagrams of both structures have some additional energy levels in the energy gap, so the resistivity is quite different from undoped 4H—SiC. When E_{F}=0.99+EV eV, in At-doped 4H—SiC, due to the additional energy traps, an energy degeneracy state is formed at the Γ point with the valence band. Compared with I-doped 4H—SiC, the carrier transition merely requires the release of phonons and the release of additional energy to enter the valence band, while for I-doped 4H—SiC, during the carrier transition, in addition to the release of phonons and additional energy, the probability of photon release transition also has to be considered. Therefore, the resistivity of At-doped 4H—SiC is lower than the resistivity of I-doped 4H—SiC. Based on the above, for doping elements At or I, the high resistivity (refer to Table 3) obtained using the n-type 4H silicon carbide standard model with the assumption that E_{F}=2.56+E_{V} eV conflicts with the low resistivity determined based on density of states and energy band. Therefore, using I or At as doping elements is not suitable for the n-type 4H silicon carbide standard model. Using the semi-insulating 4H silicon carbide standard model for simulation calculations of I or At-doped 4H—SiC may obtain more accurate results.

Referring to FIG. 5E and 6E, the energy band of F-doped 4H—SiC shows the greatest difference compared to the energy bands of other element-doped 4H—SiC. Therefore, when E_{F}=0.99+E_{V} eV, compared with other energy bands, since F doping does not generate additional energy levels for electron transitions, causing electrons to require extremely high energy to be excited, the resistivity of F-doped 4H—SiC is ∞ (refer to Table 4), which is a high resistivity value.

Therefore, using the semi-insulating 4H silicon carbide standard model for simulation calculations of F-doped 4H—SiC may obtain more accurate results.

Additionally, since it is difficult to determine from FIG. 5A and FIG. 6A whether the Ta element is used for the n-type 4H silicon carbide standard model or the semi-insulating 4H silicon carbide standard model, DLTS is used for determination. From DLTS, it is known that the trap state of Ta-doped 4H—SiC falls approximately in a range of E_{C}−0.72 eV to E_{C}−0.65 eV, and the behavior of this state is similar to a donor. Therefore, it may be inferred that the resistivity of Ta-doped 4H—SiC is suitable for the n-type 4H silicon carbide standard model with E_{F}=2.56+E_{V} eV. Therefore, using the n-type 4H silicon carbide standard model for simulation calculations of Ta-doped 4H—SiC may obtain more accurate results. That is, the resistivity of Ta-doped 4H—SiC at 300 K is approximately 1.62×10⁻² ohm cm (refer to Table 3).

Finally, returning to FIG. 2, in Step S3, the doping element is used to dope the silicon carbide substrate to obtain a doped silicon carbide substrate. Specifically, after calculating the resistivity of silicon carbide doped with various elements through the simulation software, the doping element to be used is determined according to requirements. Finally, the silicon carbide substrate doped with the doping element is actually manufactured. In some embodiments, the silicon carbide substrate is doped with at least one of Ta, Cl, I, and At, and the resistivity of the doped silicon carbide substrate is of 10⁻² to 10⁻³ ohm-cm. In some embodiments, the silicon carbide substrate is doped with F, and the resistivity of the doped silicon carbide substrate is greater than 10¹⁰ ohm-cm.

In summary, in the disclosure, before fabricating a doped silicon carbide substrate, a simulation method is first used to calculate a simulated resistivity to ensure that the silicon carbide substrate doped with the selected doping element can meet the requirements. Since the simulation software is used to calculate the resistivity of the doped silicon carbide substrate to be manufactured, the operation can save the money and time costs required to find suitable doping elements.

What is claimed is:

1. A method for manufacturing a semiconductor substrate, comprising:
using a simulation software to add a first dopant in a 4H silicon carbide supercell to obtain an n-type 4H silicon carbide supercell;
using the simulation software to add a second dopant in another 4H silicon carbide supercell to obtain a semi-insulating type 4H silicon carbide supercell;
using the simulation software to perform free energy structure optimization simulation of the n-type 4H silicon carbide supercell to establish an n-type 4H silicon carbide standard model;
using the simulation software to perform free energy structure optimization simulation of the semi-insulating type 4H silicon carbide supercell to establish a semi-insulating type 4H silicon carbide standard model;
using the simulation software to introduce a doping element into at least one of the n-type 4H silicon carbide standard model and the semi-insulating type 4H silicon carbide standard model to calculate a simulated resistivity of 4H silicon carbide doped with the doping element; and
using the doping element to dope a silicon carbide substrate to obtain a doped silicon carbide substrate.

2. The method for manufacturing as claimed in claim 1, wherein using the simulation software to introduce the doping element into the at least one of the n-type 4H silicon carbide standard model and the semi-insulating type 4H silicon carbide standard model to calculate the simulated resistivity of the 4H silicon carbide doped with the doping element comprises:
simulating and calculating a first Fermi level of the n-type 4H silicon carbide standard model;
simulating and calculating a second Fermi level of the semi-insulating type 4H silicon carbide standard model;
using the n-type 4H silicon carbide standard model to calculate a first simulated resistivity of the 4H silicon carbide doped with the doping element in the simulation software;
using the semi-insulating type 4H silicon carbide standard model to calculate a second simulated resistivity of the 4H silicon carbide doped with the doping element in the simulation software, wherein
the first simulated resistivity corresponds to an energy band diagram of the 4H silicon carbide doped with the doping element and the first Fermi level, and the first simulated resistivity is the simulated resistivity, or
the second simulated resistivity corresponds to the energy band diagram of the 4H silicon carbide doped with the doping element and the second Fermi level, and the second simulated resistivity is the simulated resistivity.

3. The method for manufacturing as claimed in claim 1, wherein using the simulation software to perform the free energy structure optimization simulation of the n-type 4H silicon carbide supercell comprises:
using actually measured energy gap and resistivity of n-type 4H silicon carbide doped with the first dopant, combined with Boltzmann transport equation, to obtain a plurality of first quantum mechanical parameters in the simulation software; and
using the simulation software to perform the free energy structure optimization simulation of the n-type 4H silicon carbide supercell based on the plurality of first quantum mechanical parameters and GGA-PBE functional.

4. The method for manufacturing as claimed in claim 3, wherein the plurality of first quantum mechanical parameters comprise plane wave cutoff energy, a spacing of k points, and self-consistent field energy convergence.

5. The method for manufacturing as claimed in claim 1, wherein using the simulation software to perform the free energy structure optimization simulation of the semi-insulating type 4H silicon carbide supercell comprises:
using actually measured energy gap and resistivity of semi-insulating type 4H silicon carbide doped with the second dopant, combined with Boltzmann transport equation, to obtain a plurality of second quantum mechanical parameters in the simulation software; and
using the simulation software to perform the free energy structure optimization simulation of the semi-insulating type 4H silicon carbide supercell based on the plurality of second quantum mechanical parameters and GGA-PBE functional.

6. The method for manufacturing as claimed in claim 5, wherein the plurality of second quantum mechanical parameters comprise plane wave cutoff energy, a spacing of k points, and self-consistent field energy convergence.

7. The method for manufacturing as claimed in claim 1, further comprising:
using the simulation software to establish a 4H silicon carbide unit cell of 1×1×1; and
repeatedly arranging 4H silicon carbide unit cells to obtain a 4H silicon carbide supercell of 2×2×2.

8. The method for manufacturing as claimed in claim 1, further comprising:
using Hall measurement to determine whether a carrier type of 4H silicon carbide doped with the doping element is an electron or a hole; and
determining whether doping with the doping element is suitable for the n-type 4H silicon carbide standard model or the semi-insulating type 4H silicon carbide standard model based on the carrier type.

9. The method for manufacturing as claimed in claim 1, wherein the doping element comprises one of Ta, P, As, Sb, Bi, F, Cl, I, At, B, Al, Ga, In, and Tl.

10. The method for manufacturing as claimed in claim 1, wherein the first dopant comprises nitrogen, and the second dopant comprises vanadium.

11. The method for manufacturing as claimed in claim 1, wherein the free energy structure optimization simulation comprises using GGA-PBE functional to execute a first principle-based VASP calculation program, plane wave cutoff energy used is of 200 eV to 550 eV, a spacing of k points is of 0.1/Ang to 0.5/Ang, and self-consistent field energy convergence is of 10⁻⁵ to 10⁻⁷ eV.

12. The method for manufacturing as claimed in claim 2, wherein the first Fermi level is at a position 2.56 eV above a valence band, and the second Fermi level is at a position 0.99 eV above the valence band.

13. A semiconductor substrate, comprising:
a silicon carbide substrate, wherein the silicon carbide substrate is doped with at least one of Ta, P, As, Sb, Bi, F, Cl, I, At, B, Al, Ga, In, and Tl.

14. The semiconductor substrate as claimed in claim 13, wherein the silicon carbide substrate 10 is doped with at least one of Ta, Cl, I, and At, and a resistivity of the silicon carbide substrate is of 10⁻² to 10⁻³ ohm-cm.

15. The semiconductor substrate as claimed in claim 13, wherein the silicon carbide substrate is doped with F, and a resistivity of the silicon carbide substrate is greater than 10¹⁰ ohm-cm.
